(19) United States
(12) Patent Application Publication
(10) Pub. No.: US 2025/0046650 A1
(43) Pub. Date: Feb. 6, 2025

(54) METHOD OF WAFER BONDING

(71) Applicant: WAFER WORKS CORPORATION, Taoyuan City (TW)

(72) Inventors: Wei-Jing CHENG, Taoyuan City (TW); Cheng-Fu FAN, Taoyuan City (TW)

(21) Appl. No.: 18/516,981

(22) Filed: Nov. 22, 2023

(30) Foreign Application Priority Data
Aug. 4, 2023 (TW) 112129475

(51) Int. Cl. H01L 23/00

(52) U.S. Cl. CPC H01L 21/76251; H01L 21/0201; H01L 21/67017

(57) ABSTRACT

A method of wafer bonding includes the following operations. A first surface of the handle wafer, a second surface of the device wafer, or a combination thereof, is coated with water. When the first surface of the handle wafer is coated with water, the handle wafer is rotated at a first rotational speed. When the second surface of the device wafer is coated with water, the device wafer is rotated at a second rotational speed. When the first surface of the handle wafer and the second surface of the device wafer are coated with water, the handle wafer is rotated at a third rotational speed, and the device wafer is rotated at a fourth rotational speed. The first surface of the handle wafer and the second surface of the device wafer are bonded.

### CROSS-REFERENCE TO RELATED APPLICATION

This application claims priority to Taiwan Application Serial Number 112129475, filed Aug. 4, 2023, which is herein incorporated by reference.

### BACKGROUND

### Field of Invention

The present disclosure relates to a method of fabricating a semiconductor structure, and more particularly to a method of wafer bonding.

### Description of Related Art

Wafer bonding technology is to align and attach two wafers by van der Waals force or electrostatic force, and then provide external energy to form a chemical bond at the interface, thereby bonding the wafers to each other. During the bonding process, the wafers may need to be heated to a high temperature, or the surfaces of the wafers may need to be treated before bonding. However, there may be problems with uneven heating of the wafers or complex treating procedures. In view of this, there is an urgent need to develop a new wafer bonding method.

### SUMMARY

The present disclosure provides a method of wafer bonding including the following operations. A handle wafer and a device wafer are received. A first surface of the handle wafer, a second surface of the device wafer, or a combination thereof is coated with water. When the first surface of the handle wafer is coated with the water, the handle wafer rotates at a first rotational speed. When the second surface of the device wafer is coated with the water, the device wafer rotates at a second rotational speed. When the first surface of the handle wafer and the second surface of the device wafer are coated with the water, the handle wafer rotates at a third rotational speed, and the device wafer rotates at a fourth rotational speed. The first surface of the handle wafer and the second surface of the device wafer are bonded.

In some embodiments, the water has a resistance value ranging from about 0.5 MΩ·cm to about 18.3 MΩ·cm.

In some embodiments, the first rotational speed, the second rotational speed, the third rotational speed, and the fourth rotational speed are independently about 1500 rpm to about 3500 rpm.

In some embodiments, the method further includes: before coating the first surface of the handle wafer, the second surface of the device wafer, or the combination thereof with the water, treating the first surface, the second surface, or the combination thereof with plasma.

In some embodiments, during treating the first surface of the handle wafer, the second surface of the device wafer, or the combination thereof with the plasma, a bombardment time of the plasma is from 15 seconds to 30 seconds.

In some embodiments, the plasma includes an oxygen plasma, a nitrogen plasma, an argon plasma, or combinations thereof.

In some embodiments, coating the first surface of the handle wafer, the second surface of the device wafer, or the combination thereof with the water includes: providing the water and a gas with a nozzle to spray the water onto the first surface, the second surface, or the combination thereof.

In some embodiments, when providing the water and the gas with the nozzle, a flow rate of the water is about 0.14 L/min to about 0.22 L/min, and a flow rate of the gas is about 40 L/min to about 75 L/min.

In some embodiments, at least one of the handle wafer and the device wafer includes a wafer body and an insulating layer, and the insulating layer covers the wafer body.

In some embodiments, bonding the first surface of the handle wafer and the second surface of the device wafer is performed at about 180° C. to about 1100° C.

In some embodiments, bonding the first surface of the handle wafer and the second surface of the device wafer is performed at about 180° C. to about 600° C.

The present disclosure provides a method of wafer bonding including the following operations. A handle wafer and a device wafer are received. A first surface of the handle wafer, a second surface of the device wafer, or a combination thereof is treated with plasma. The first surface treated with the plasma, the second surface treated with the plasma, or a combination thereof is coated with water. The first surface of the handle wafer and the second surface of the device wafer are bonded.

In some embodiments, the plasma includes an oxygen plasma, a nitrogen plasma, an argon plasma, or combinations thereof.

In some embodiments, bonding the first surface of the handle wafer and the second surface of the device wafer is performed at about 180° C. to about 1100° C.

In some embodiments, at least one of the handle wafer and the device wafer includes a wafer body and an insulating layer, and the insulating layer covers the wafer body.

In some embodiments, the water has a resistance value ranging from about 0.5 MΩ·cm to about 18.3 MΩ·cm.

In some embodiments, the water does not include ammonia, a chelating agent, a surfactant, or combinations thereof.

In some embodiments, during treating the first surface of the handle wafer, the second surface of the device wafer, or the combination thereof with the plasma, a bombardment time of the plasma is from 15 seconds to 30 seconds.

In some embodiments, coating the first surface treated with the plasma, the second surface treated with the plasma, or the combination thereof with the water includes: providing the water and a gas with a nozzle to spray the water onto the first surface, the second surface, or the combination thereof.

In some embodiments, the method further includes before treating the first surface of the handle wafer, the second surface of the device wafer, or the combination thereof with the plasma, generating the plasma by an upper electrode and a lower electrode, in which the upper electrode and the lower electrode are respectively connected to radio frequency power supplies with a frequency of about 40 kHz to about 400 KHz.

### BRIEF DESCRIPTION OF THE DRAWINGS

The present disclosure can be more fully understood by reading the following detailed description of the embodiment, with reference made to the accompanying drawings as follows.

FIG. 1 is a schematic cross-sectional view of treating a wafer with plasma according to various embodiments of the present disclosure.

FIG. 2 is a schematic cross-sectional view of coating a wafer with water according to various embodiments of the present disclosure.

FIGS. 3-4 are thickness distribution diagrams of a surface modification layer on a silicon wafer according to various embodiments of the present disclosure.

FIGS. 5, 6, 8, and 9 are schematic cross-sectional views of bonding a handle wafer and a device wafer according to various embodiments of the present disclosure.

FIG. 7 is a graph of bonding strength versus annealing temperature for various embodiments of the present disclosure.

### DETAILED DESCRIPTION

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

The term “about,” “approximately,” “essentially,” or “substantially” as used herein is inclusive of the stated value and means within an acceptable range of deviation for the particular value as determined by persons of ordinary skill in the art, considering the measurement in question and the error associated with measurement of the particular quantity (i.e., the limitations of the measurement system). For example, “about” may mean within one or more standard deviations, or within, for example, +30%, +20%, +15%, +10%, +5% of the stated value. Moreover, a relatively acceptable range of deviation or standard deviation may be chosen for the term “about,” “approximately,” “essentially” or “substantially” as used herein based on measuring properties, coating properties, or other properties, instead of applying one standard deviation across all the properties.

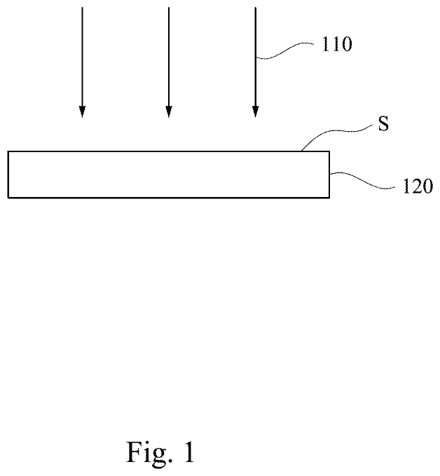

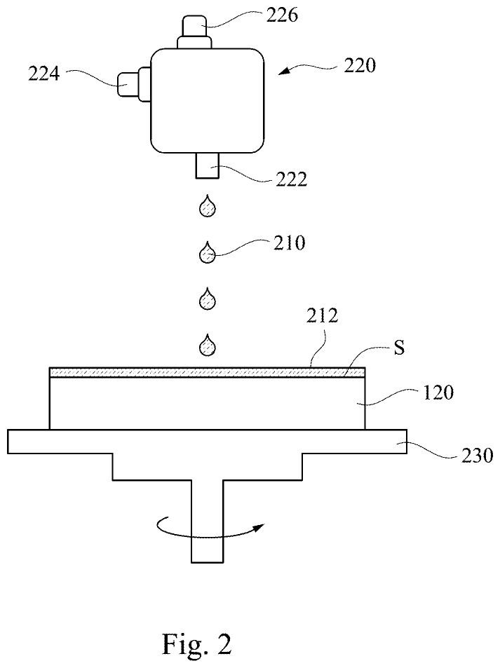

The present disclosure provides a method for treating a wafer surface. The surface of the wafer is treated with plasma, and then the surface of the wafer is coated or cleaned with water. The surface of the wafer can be treated with the plasma and the water to enhance the bonding strength between the surface of the wafer and the surface of another wafer. In some embodiments, the materials of the two wafers are the same or different. FIG. 1 is a schematic cross-sectional view of treating a wafer with plasma according to various embodiments of the present disclosure. FIG. 2 is a schematic cross-sectional view of coating a wafer with water according to various embodiments of the present disclosure.

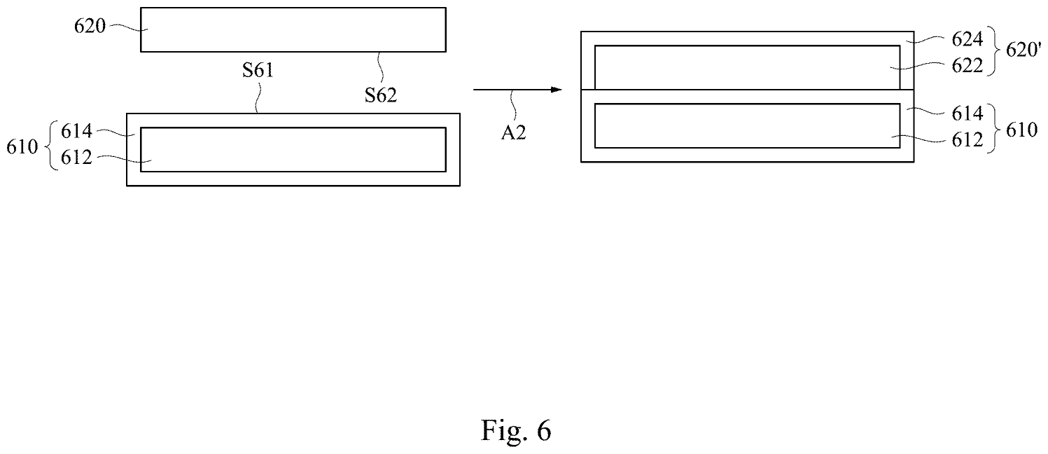

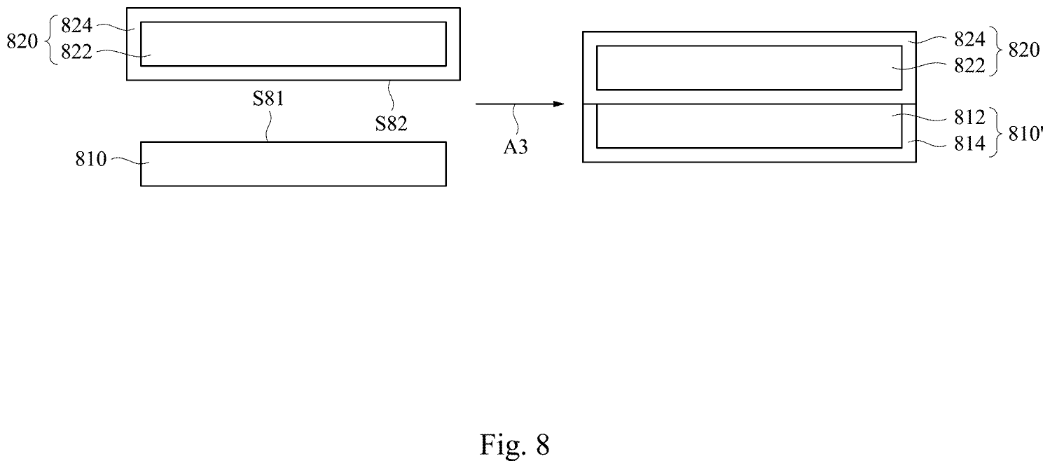

As shown in FIG. 1, a surface S of a wafer 120 is treated with plasma 110. The wafer 120 is, for example, a handle wafer or a device wafer, and the outer surface of the wafer 120 is not covered by an insulating layer. In some other embodiments, the wafer 120 includes a wafer body and an insulating layer covering the wafer body. For a schematic cross-sectional view of the wafer 120, refer to a handle wafer 610 in FIG. 6 or a device wafer 820 in FIG. 8. In some embodiments, the handle wafer, the device wafer, or the wafer body independently includes silicon, silicon carbide, quartz, gallium nitride, aluminum oxide, combinations thereof, or other suitable semiconductor materials. The handle wafer, the device wafer, or the wafer body is, for example, sapphire. In some embodiments, the insulating layer includes an insulating oxide, an insulating nitride, a combination thereof, or other suitable insulating materials, such as silicon dioxide or silicon nitride. In some embodiments, the insulating layer is formed by chemical vapor deposition or oxidizing a portion of the wafer 120.

In some embodiments, the plasma 110 includes an oxygen plasma, a nitrogen plasma, an argon plasma, or combinations thereof. In some embodiments, the bombardment time of the plasma 110 is from 15 seconds to 30 seconds, such as 15, 20, 25, or 30 seconds. Specifically, the wafer 120 can be placed in a chamber, and the plasma 110 is generated by upper and lower electrodes that can excite oxygen, nitrogen, argon, or combinations thereof. After the surface S of the wafer 120 is treated (bombarded) with the plasma 110, the plasma 110 may break weaker bonds, thereby forming a surface modification layer (not shown) having different thicknesses and free radicals. The surface modification layer includes an oxide of the wafer 120, such as silicon dioxide. In some embodiments, the upper and lower electrodes are respectively connected to radio frequency power supplies with a frequency of about 40 kHz to about 400 kHz. In some embodiments, the upper electrode is connected to a radio frequency power supply with a frequency of 400 kHz, and the lower electrode is connected to a radio frequency power supply with a frequency of 40 KHz. In some embodiments, the radio frequency power supplies have a power of 25 W to 120 W, such as 25, 30, 40, 50, 60, 70, 80, 90, 100, 110, or 120 W. The surface modification layer has good hydrophilicity, and its water droplet contact angle is less than 5 degrees. In some embodiments, the surface modification layer has a thickness of about 2.5 nm to about 4.5 nm, and its film thickness unevenness is less than 5%. In other words, the surface modification layer has good uniformity. Bonding two wafer 120 (such as handle wafer or device wafer) treated with the plasma 110 to each other at about 180° C. to about 1100° C. can achieve a bonding strength of 0.4 J/m² to 2.3 J/m², such as 0.4, 0.5, 1, 1.5, 2, or 2.3 J/m².

Next, the surface S of the wafer 120 with the free radicals, which is treated with the plasma, is coated with water. The water can be grafted to the surface S of the wafer 120, so that the surface S of wafer 120 has hydroxyl groups (—OH), thereby improving the hydrophilicity of the wafer 120. The water is, for example, deionized water (pure water). In some embodiments, the water has a resistance value ranging from about 0.5 MΩ·cm to about 18.3 MΩ·cm, such as 0.5, 1, 2, 3, 4, 5, 6, 7, 8, 9, 10, 11, 12, 13, 14, 15, 16, 17, 18, or 18.3 MΩ·cm. In some embodiments, the water does not include ammonia (NH₃), a chelating agent, a surfactant, or combinations thereof. Regardless of whether the wafer 120 is treated with the plasma 110 or not, if the wafer 120 coated with the water is bonded to another wafer through a thermal process (such as an annealing process), the water layer 212 on the surface S of the wafer 120 can improve the heating uniformity of the wafer 120, thereby improving the bonding strength of the two wafers. It can be seen that the present disclosure provides a simple method for treating a wafer surface.

In some embodiments, refer to FIG. 2 for the embodiment of coating. As shown in FIG. 2, a nozzle 222 of a spraying device 220 is used to provide water 210 and gas to spray the water 210 onto the surface S of the wafer 120. More specifically, water can be introduced through a first pipeline 224, gas can be introduced through a second pipeline 226, and then the water 210 and the gas can be sprayed simultaneously through the nozzle 222. The water droplets can be atomized by the gas, and the size of the sprayed water droplets can be controlled so that the water droplets can be more evenly distributed on the surface S of the wafer 120. The improvement of the distribution uniformity of water droplets can also improve the heating uniformity of the wafer 120 during a thermal process. In some embodiments, the gas is nitrogen gas, an inert gas, or a combination thereof. In some embodiments, during the process of coating the water 210, the wafer 120 rotates at a rotational speed, so the water 210 can be distributed on the surface S of the wafer 120 by centrifugal force, thereby forming the water layer 212, which covers the surface S of the wafer 120. During the process of coating the water 210, rotating the wafer 120 can make the water droplets be more evenly distributed on the surface S of the wafer 120, thereby improving the heating uniformity of the wafer 120 during the thermal process. In addition, rotating the wafer 120 is also helpful in removing excess water. For example, the wafer 120 can be fixed on a rotator 230, and the wafer 120 can be rotated by the rotator 230.

In some embodiments, when the water 210 and the gas are provided by the nozzle 222, a flow rate of the water 210 is about 0.14 L/min to about 0.22 L/min, such as 0.14, 0.15, 0.16, 0.17, 0.18, 0.19, 0.20, 0.21, or 0.22 L/min. If the flow rate of the water 210 is less than about 0.14 L/min, the spraying time may be too long, or the spraying amount may be insufficient. If the flow rate of the water 210 is greater than about 0.22 L/min, the water droplet size may be too large. In some embodiments, when the water 210 and the gas are provided by the nozzle 222, a flow rate of the gas is about 40 L/min to about 75 L/min, such as 40, 42, 50, 55, 60, 65, 70, or 75 L/min. If the flow rate of the gas is less than about 40 L/min (for example, 35 L/min) or greater than about 75 L/min (for example, 85 L/min or 90 L/min), it may be detrimental to uniform spraying, thereby reducing the distribution uniformity of the water droplets on the wafer surface, which reduces the heating uniformity of the wafer. Therefore, if a wafer is bonded to another wafer, damage to the wafers may be observed after bonding. When the flow rate of the water 210 and/or the flow rate of the gas falls within the above numerical range, the water droplet size can be facilitated for spraying, thereby improving the distribution uniformity of the water droplets. For example, the size can be less than 2.6 nm. In some embodiments, the rotational speed of the wafer 120 is about 1500 rpm to about 3500 rpm, such as 1500, 2000, 2500, 3000, or 3500 rpm. When the rotational speed falls within the above numerical range, the water layer 212 can be evenly distributed on the surface S of the wafer 120, thereby improving the heating uniformity of the wafer 120 during the thermal process. If the rotational speed falls outside the above numerical range, the water layer 212 of the surface S of the wafer 120 may be unevenly distributed.

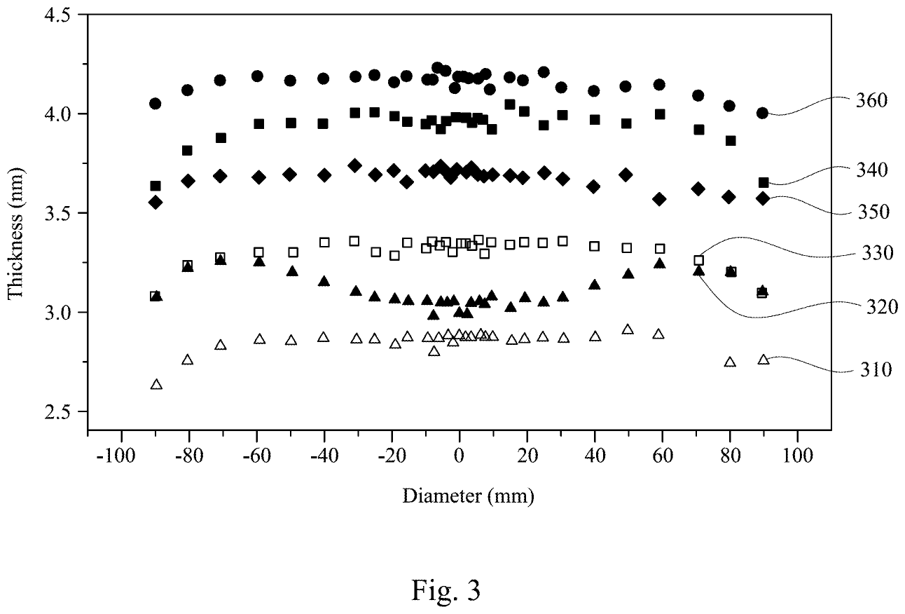

Please refer to FIGS. 1 and 3. FIG. 3 is a thickness distribution diagram of a surface modification layer on a silicon wafer according to various embodiments of the present disclosure. The silicon wafer is bombarded with argon plasma for 15 seconds to obtain data points 310. The silicon wafer is bombarded with argon plasma for 30 seconds to obtain data points 320. The silicon wafer is bombarded with nitrogen plasma for 15 seconds to obtain data points 330. The silicon wafer is bombarded with nitrogen plasma for 30 seconds to obtain data points 340. The silicon wafer is bombarded with oxygen plasma for 15 seconds to obtain data points 350. The silicon wafer is bombarded with oxygen plasma for 30 seconds to data points 360. The upper electrode and the lower electrode for generating plasma are respectively connected to a 400 kHz radio frequency power supply with a power of 60 W and a 40 kHz radio frequency power supply with a power of 25 W. From the data points 310, 320, 330, 340, 350, and 360, it can be known that the film thickness unevenness of the surface modification layers is 4.5%, 4.8%, 4.3%, 5.2%, 2.5%, and 2.7%, respectively, so the surface modification layers of the present disclosure have good uniformity.

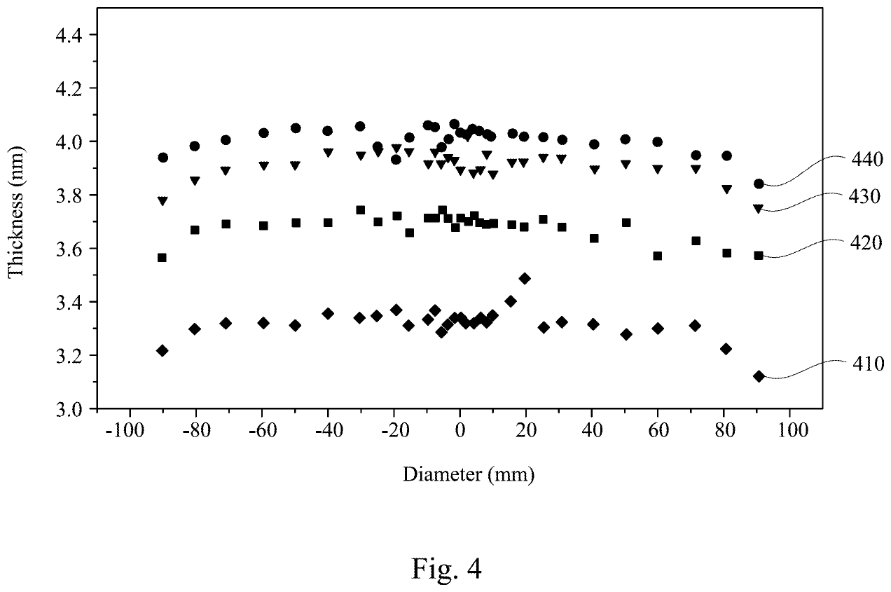

Please refer to FIG. 1 and FIG. 4. FIG. 4 is a thickness distribution diagram of a surface modification layer on a silicon wafer according to various embodiments of the present disclosure. The silicon wafer is bombarded with oxygen plasma for 15 seconds. The upper electrode and lower electrode for generating plasma are respectively connected to a 400 kHz radio frequency power supply with a power of 30 W, 60 W, 90 W, or 120 W, and a 40 kHz radio frequency power supply with a matching power of 12.5 W, 25 W, 37.5 W, or 50 W. Data points 410, 420, 430, 440 are obtained respectively. It can be known that the film thicknesses of the surface modification layers can be reduced by reducing the power of the radio frequency power supply.

The present disclosure provides another method of treating a wafer surface by coating the surface S of the wafer 120 with water 210. The surface S of the wafer 120 can be treated with the water 210 to enhance the bonding strength between the surface S of the wafer 120 and the surface of another wafer. FIG. 2 is a schematic cross-sectional view of coating the wafer 120 with the water 210 according to various embodiments of the present disclosure. In some embodiments, before coating the surface S of the wafer 120 with the water 210, the surface S of wafer 120 is not treated with plasma. Specifically, the surface S of wafer 120 is not treated with an oxygen plasma, a nitrogen plasma, an argon plasma, or combinations thereof. Therefore, in the present disclosure, the bonding strength between the surface S of the wafer 120 and the surface of another wafer can be enhanced by coating the wafer 120 with the water 210 only. Please refer to the aforementioned embodiments for the embodiments and effects of coating water, which will not be described again.

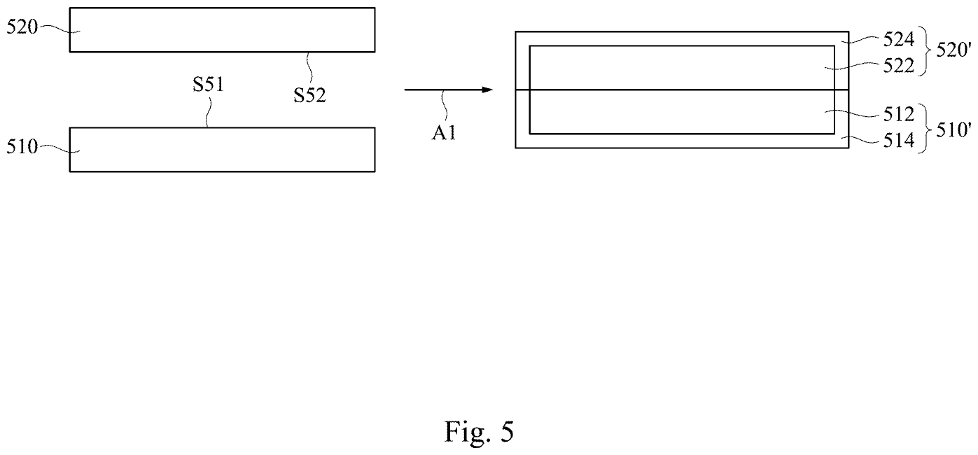

FIGS. 5, 6, 8, and 9 are schematic cross-sectional views of bonding a handle wafer and a device wafer according to various embodiments of the present disclosure.

The present disclosure provides a method of wafer bonding. Please refer to FIG. 2 and FIG. 5. As shown in FIG. 5, a handle wafer 510 and a device wafer 520 are received. In some embodiments, the materials of the handle wafer 510 and the device wafer 520 are the same or different. Referring to the aforementioned embodiments in FIG. 2, the first surface S51 of the handle wafer 510, the second surface S52 of the device wafer 520, or a combination thereof is coated with water. In some embodiments, when the first surface S51 of the handle wafer 510 is coated with the water, the handle wafer 510 rotates at a first rotational speed. In some embodiments, when the second surface S52 of the device wafer 520 is coated with the water, the device wafer 520 rotates at a second rotational speed. In some embodiments, when the first surface S51 of the handle wafer 510 and the second surface S52 of the device wafer 520 are coated with the water, the handle wafer 510 rotates at a third rotational speed, and the device wafer 520 rotates at a fourth rotational speed. In some embodiments, the first rotational speed, the second rotational speed, the third rotational speed, and the fourth rotational speed are independently about 1500 rpm to about 3500 rpm. After the water is coated, the first surface S51 and the second surface S52 are bonded as shown in FIG. 5. In some embodiments, an annealing process A1 is performed to bond the first surface S51 and the second surface S52. For example, bonding the first surface S51 and the second surface S52 is performed at about 900° C. to about 1100° C. The bonding temperature is, for example, 900, 950, 1000, 1050, or 1100° C. The outer surfaces of the handle wafer 510 and the device wafer 520 may be oxidized by the annealing process A1, thereby forming a handle wafer 510′ and a device wafer 520′, the handle wafer 510′ includes a wafer body 512 and an insulating layer 514 covering the wafer body 512, and the device wafer 520′ includes a wafer body 522 and an insulating layer 524 covering the wafer body 522.

Please continue to refer to FIG. 5. In some embodiments, the method of wafer bonding further includes: before coating the first surface S51 of the handle wafer 510, the second surface S52 of the device wafer 520, or the combination thereof with the water, the first surface S51, the second surface S52, or the combination thereof is treated with plasma. For example, referring to the aforementioned embodiments in FIG. 1 and FIG. 2, the first surface S51, the second surface S52, or the combination thereof is treated with the plasma, and then the first surface S51 treated with the plasma, the second surface S52 treated with the plasma, or a combination thereof is treated with water. Next, the first surface S51 and the second surface S52 are bonded. In some embodiments, the annealing process A1 is performed to bond the first surface S51 and the second surface S52. For example, bonding the first surface S51 and the second surface S52 is performed at about 180° C. to about 1100° C. The bonding temperature is, for example, 180, 200, 250, 300, 350, 400, 450, 500, 550, 600, 650, 700, 750, 800, 850, 900, 950, 1000, 1050, or 1100° C. It is worth noting that when the wafer surface is treated with the plasma, the temperature of the annealing process A1 can be reduced. Bonding the wafers at low temperatures (such as 180° C. to 600° C.) can still produce an interface with high bonding strength, thereby saving energy required for bonding, increasing productivity, and preventing high temperatures from affecting the performance of the overall structure. The plasma treatment is beneficial to lowering the annealing temperature. The interfacial bonding strength obtained by bonding wafers at low temperatures is roughly similar to the interfacial bonding strength obtained by bonding wafers at high temperatures (for example, 1050° C.).

In some embodiments, the method further includes: after treating with the water or the plasma and water and before bonding the first surface S51 and the second surface S52, pre-bonding (alignment bonding) between the handle wafer 510 and the device wafer 520 is performed. In some embodiments, the pre-bonding temperature is from about 20° C. to about 30° C. After treating the surfaces of two wafers with the water and plasma, the two pre-bonded wafers can already have a certain degree of bonding strength. Therefore, in the annealing process A1, the interfacial bonding strength obtained by bonding the two wafers at low temperatures is roughly similar to the interfacial bonding strength obtained by bonding the two wafers at high temperatures.

The present disclosure provides a method of wafer bonding. Please refer to FIG. 2 and FIG. 6. As shown in FIG. 6, a handle wafer 610 and a device wafer 620 are received. For the embodiments (rotational speed, bonding temperature) and effects of FIG. 6, please refer to the embodiments of FIG. 5. For the device wafer 620 in FIG. 6, directly refer to the device wafer 520 in FIG. 5. The handle wafer 610 in FIG. 6 includes a wafer body 612 and an insulating layer 614 covering the wafer body 612. The difference between the handle wafer 610 and the handle wafer 510 in FIG. 5 is that the handle wafer 610 further includes the insulating layer 614. Referring to the aforementioned embodiments in FIG. 2, the first surface S61 of the handle wafer 610, the second surface S62 of the device wafer 620, or a combination thereof is coated with water. The first surface S61 of the handle wafer 610 is the surface of the insulating layer 614. After coating the water, as shown in FIG. 6, the first surface S61 and the second surface S62 are bonded by using an annealing process A2. The outer surface of the device wafer 620 may be oxidized due to the annealing process A2, thereby forming a device wafer 620′, which includes a wafer body 622 and an insulating layer 624 covering the wafer body 622. The thickness of the insulating layer 614 of the handle wafer 610 may increase or remain substantially unchanged after annealing.

Please continue to refer to FIG. 6. In some embodiments, the method of wafer bonding further includes: before coating the first surface S61 of the handle wafer 610, the second surface S62 of the device wafer 620, or the combination thereof with water, the first surface S61, the second surface S62, or the combination thereof is treated with plasma. For example, referring to the embodiments in FIG. 1 and FIG. 2, the first surface S61, the second surface S62, or the combination thereof is treated with plasma, and then the first surface S61 treated with the plasm, the second surface S62 treated with the plasma, or a combination thereof is treated with water. Next, the first surface S61 and the second surface S62 are bonded. In some embodiments, the annealing process A2 is performed to bond the first surface S61 and the second surface S62. Please refer to the aforementioned embodiments of bonding the first surface S51 and the second surface S52 for the embodiments (temperature) and effects of bonding, which will not be described again.

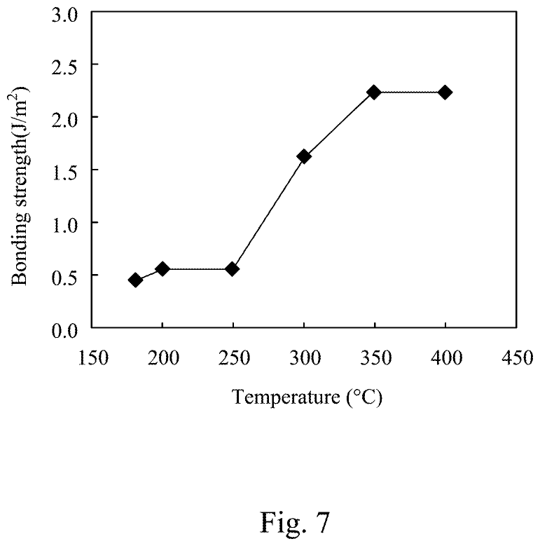

In some embodiments, the wafer is treated with plasma, but the wafer is not coated with water. Please refer to FIG. 1 and FIG. 6. The handle wafer 610 and the device wafer 620 are respectively bombarded with a nitrogen plasma, an oxygen plasma, an argon plasma, or combinations thereof. The bombardment time is 15 seconds or 30 seconds. The upper electrode and the lower electrode used to generate plasma are respectively connected to a 400 kHz radio frequency power supply and a 40 kHz radio frequency power supply. The power of the radio frequency power supplies is 25 W to 120 W. Specifically, through the plasma treatment, surface modification layers (not shown) of different thicknesses can be formed on the handle wafer 610 and the device wafer 620. The water droplet contact angles of the surface modified layers are less than 5 degrees. Two wafers treated with the plasma and boned to each other at about 180° C. to about 1100° C. can achieve a bonding strength of 0.4 J/m² to 2.3 J/m². FIG. 7 is a graph of bonding strength versus annealing temperature for various embodiments of the present disclosure. Please refer to FIG. 1 and FIG. 6. The handle wafer 610 and the device wafer 620 were bombarded with an oxygen plasma. The material of the device wafer 620 was silicon, the material of the wafer body 612 of the handle wafer 610 was silicon, and the insulating layer 614 was a silicon dioxide layer. The bombardment time was 15 seconds. The upper electrode and the lower electrode for generating plasma were respectively connected to a 400 kHz radio frequency power supply and a 40 kHz radio frequency power supply. The power of the radio frequency power supplies was 25 W. The handle wafer 610 and device wafer 620 were bonded under normal pressure and different annealing temperatures. Please refer to FIG. 7 for the test results of the bonding strength. It can be seen that when the annealing temperature is higher than about 300° C., the bonding strength can be higher than about 1.5 J/m². When the annealing temperature is higher than about 350° C., the bonding strength approaches the bonding strength of bulk silicon (about 2.5 J/m²).

The present disclosure provides a method of wafer bonding. Please refer to FIG. 2 and FIG. 8. As shown in FIG. 8, a handle wafer 810 and a device wafer 820 are received. For the embodiments (rotational speed, bonding temperature) and effects of FIG. 8, please refer to the embodiments of FIG. 5. For the handle wafer 810 in FIG. 8, directly refer to the handle wafer 510 in FIG. 5. The device wafer 820 in FIG. 8 includes a wafer body 822 and an insulating layer 824 covering the wafer body 822. The difference between the device wafer 820 and the device wafer 520 in FIG. 5 is that the device wafer 820 further includes the insulating layer 824. Referring to the aforementioned embodiments in FIG. 2, the first surface S81 of the handle wafer 810, the second surface S82 of the device wafer 820, or a combination thereof is coated with water. The first surface S81 of the handle wafer 810 is the surface of the insulating layer 824. After coating the water, as shown in FIG. 8, the first surface S81 and the second surface S82 are bonded by using an annealing process A3. The outer surface of the handle wafer 810 may be oxidized due to the annealing process A3, thereby forming a handle wafer 810′, which includes a wafer body 812 and an insulating layer 814 covering the wafer body 812. The thickness of the insulating layer 824 of the device wafer 820 may increase or remain substantially unchanged after annealing.

Please continue to refer to FIG. 8. In some embodiments, the method of wafer bonding further includes: before coating the first surface S81 of the handle wafer 810, the second surface S82 of the device wafer 820, or the combination thereof with water, the first surface S81, the second surface S82, or the combination thereof is treated with plasma. For example, referring to the embodiments in FIG. 1 and FIG. 2, the first surface S81, the second surface S82, or the combination thereof is treated with plasma, and then the first surface S81 treated by the plasma, the second surface S82 treated with plasma, or a combination thereof is treated with water. Next, the first surface S81 and the second surface S82 are bonded. In some embodiments, the annealing process A3 is performed to bond the first surface S81 and the second surface S82. Please refer to the aforementioned embodiments of bonding the first surface S51 and the second surface S52 for the embodiments (temperature) and effects of bonding, which will not be described again.

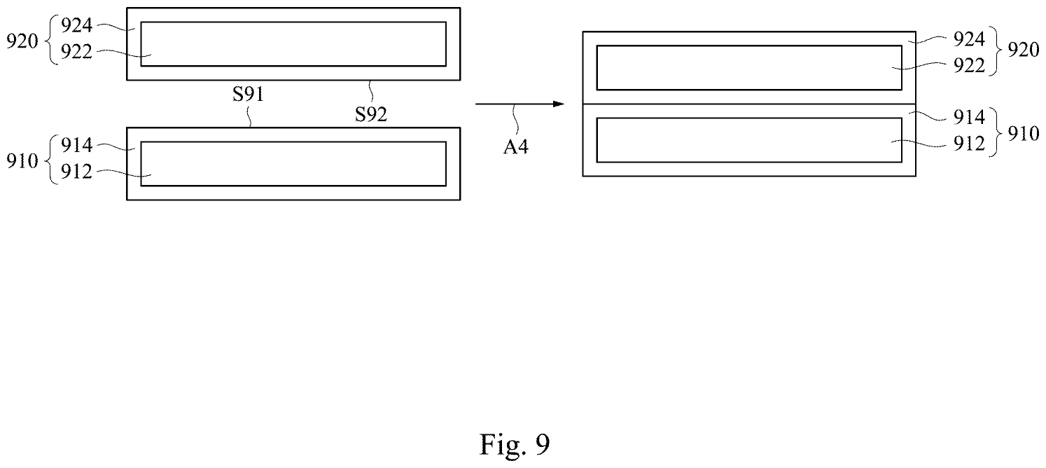

The present disclosure provides a method of wafer bonding. Please refer to FIG. 2 and FIG. 9. As shown in FIG. 9, a handle wafer 910 and a device wafer 920 are received. For the embodiments (rotational speed, bonding temperature) and effects of FIG. 9, please refer to the embodiments of FIG. 5. The handle wafer 910 in FIG. 9 includes a wafer body 912 and an insulating layer 914, and the insulating layer 914 covers the wafer body 912. The difference between the handle wafer 910 and the handle wafer 510 in FIG. 5 is that the handle wafer 910 further includes an insulating layer 914. The device wafer 920 in FIG. 9 includes a wafer body 922 and an insulating layer 924. The insulating layer 924 covers the wafer body 922. The difference between the device wafer 920 and the device wafer 520 in FIG. 5 is that the device wafer 920 further includes the insulating layer 924. Referring to the aforementioned embodiments in FIG. 2, the first surface S91 of the handle wafer 910, the second surface S92 of the device wafer 920, or a combination thereof is coated with water. The first surface S91 of the handle wafer 910 is the surface of the insulating layer 914, and the second surface S92 of the device wafer 920 is the surface of the insulating layer 924. After coating the water, as shown in FIG. 9, the first surface S91 and the second surface S92 are bonded by an annealing process A4. The thicknesses of the insulating layers 914, 924 may increase or remain substantially unchanged after the annealing process A4.

Please continue to refer to FIG. 9. In some embodiments, the method of bonding wafer further includes: before coating the first surface S91 of the handle wafer 910, the second surface S92 of the device wafer 920, or the combination thereof with water, the first surface S91, the second surface S92, or the combination thereof is treated with plasma. For example, referring to the embodiments in FIG. 1 and FIG. 2, the first surface S91, the second surface S92, or the combination thereof is treated with plasma, and then the first surface S91 treated with the plasma, the second surface S92 treated with the plasma, or a combination thereof is treated with water. Next, the first surface S91 and the second surface S92 are bonded. In some embodiments, the annealing process A4 is performed to bond the first surface S91 and the second surface S92. Please refer to the aforementioned embodiments of bonding the first surface S51 and the second surface S52 for the embodiments (temperature) and effects of bonding, which will not be described again. In some embodiments, the insulating layer 914 and the insulating layer 924 are silicon dioxide layers. After treating with the plasma and water, the bonding strength between the insulating layer 914 and the insulating layer 924 can be higher than 1 J/m².

Please refer to FIG. 5 again. In some embodiments, before bonding, the first surface S51 is treated with water, plasma, or a combination thereof or is not treated with water, plasma, or a combination thereof, and the second surface S52 is treated with water, plasma, or a combination thereof or is not treated with water, plasma, or a combination thereof. Moreover, at least one of the first surface S51 and the second surface S52 is treated with water, plasma, or a combination thereof. Similarly, please refer to the aforementioned embodiments of bonding the first surface S51 and the second surface S52 for the embodiments of the first surface S61 and the second surface S62 in FIG. 6, the first surface S81 and the second surface S82 in FIG. 8, or the first surface S91 and the second surface S92 in FIG. 9, which will not be described again. The processes of FIG. 6, FIG. 8, or FIG. 9 can be applied to manufacture silicon-on-insulator (SOI) wafers.

The following describes the features of the present disclosure more specifically with reference to Experiments 1-2 and Comparative experiment 1. Although the following experiments are described, the materials used, their amounts and ratios, processing details, and processing procedures may be changed as appropriate without going beyond the scope of the present disclosure. Accordingly, the present disclosure should not be interpreted restrictively by the examples described below.

### Experiment 1: Bonding Wafers

Please refer to FIG. 2 and FIG. 6, with the spraying device 220 in FIG. 2, the first surface S61 of the handle wafer 610 and the second surface S62 of the device wafer 620 were respectively sprayed with water with a flow rate of 0.2 L/min and a resistance value of 18 MΩ·cm and nitrogen gas with a flow rate of 40 L/min. The material of the device wafer 620 was silicon, the material of the wafer body 612 of the handle wafer 610 was silicon, and the insulating layer 614 was a silicon dioxide layer. The rotational speeds of the handle wafer 610 and the device wafer 620 were 2500 rpm. A thermal annealing was performed at normal pressure and 1050° C. to bond the handle wafer 610 and the device wafer 620, in which the bonding strength between the two wafers was 1.5 J/m².

### Experiment 2: Bonding Wafers

Please refer to FIG. 6, the handle wafer 610 and the device wafer 620 were bombarded with oxygen plasma, in which the material of the device wafer 620 was silicon, the material of the wafer body 612 of the handle wafer 610 was silicon, and the insulating layer 614 was a silicon dioxide layer. The bombardment time was 15 seconds. The upper electrode and the lower electrode for generating plasma were respectively connected to a 400 KHz radio frequency power supply and a 40 kHz radio frequency power supply. The power of the radio frequency power supplies was 25 W. After the plasma treatment, a surface modification layer with a thickness of about 2.5 nm to about 4.5 nm was formed on the device wafer 620 or handle wafer 610, its film thickness non-uniformity was less than 5%, and the water droplet contact angle is less than 5 degrees. With the spraying device 220 shown in FIG. 2, the handle wafer and the device wafer were respectively sprayed with water with a flow rate of 0.2 L/min and a resistance value of 18 MΩ·cm and nitrogen gas with a flow rate of 40 L/min. The rotational speeds of the handle wafer and the device wafer were 2500 rpm. A thermal annealing was performed at normal pressure and at different annealing temperatures to bond the handle wafer 610 and the device wafer 620, in which the thicknesses of the device wafer 620 and the handle wafer 610 were both 725 μm. Please refer to Table 1 below for experimental results. The way to calculate the bonding strength is as follows. After the handle wafer 610 and the device wafer 620 were bonded, a blade (or other hard and thin device) was inserted into the bonding interface between the wafers, thereby causing a crack to extend from the edge to the inside and warping the two wafers. The bonding strength (γ) is calculated by the following formula (1), in which E is the Young's coefficient, h is the blade thickness, t is the wafer thickness, and L is the length of the crack extending from the edge to the inside.

$$γ = \frac{3 E {t}^{3} {h}^{2}}{32 {L}^{4}} \qquad formula ( 1 )$$

TABLE 1

| Example | 1 | 2 | 3 | 4 | 5 | 6 |
|---|---|---|---|---|---|---|
| Annealing temperature (° C.) | 180 | 200 | 250 | 300 | 350 | 400 |
| Crack length (mm) | 18 | 17 | 17 | 13 | 12 | 12 |
| Bonding strength (J/m²) | 0.44 | 0.56 | 0.56 | 1.63 | 2.24 | 2.24 |

### Comparative Experiment 1: Bonding Wafers

Please refer to FIG. 6. The handle wafer 610 and the device wafer 620 were bombarded with argon plasma, in which the material of the device wafer 620 was silicon, the material of the wafer body 612 of the handle wafer 610 was silicon, and the insulating layer 614 was a silicon dioxide layer. The bombardment time was 15 seconds. The upper electrode and the lower electrode for generating plasma were respectively connected to a 400 kHz radio frequency power supply and a 40 kHz radio frequency power supply. The power of the radio frequency power supplies was 30 W. With the spraying device 220 shown in FIG. 2, the handle wafer 610 and the device wafer 620 were respectively sprayed with water with a flow rate of 0.2 L/min and a resistance value of 18 MΩ·cm and nitrogen gas with a flow rate of 90 L/min. The rotational speeds of the handle wafer 610 and the device wafer 620 were 2500 rpm. A thermal annealing was performed at normal pressure and 180° C. to 1100° C. to bond the handle wafer 610 and the device wafer 620. Traces of damage caused by water expansion at high temperatures during the annealing process could be seen on both wafers. It can be seen that if the flow rate of the nitrogen gas is too high, the uniformity of water droplet distribution on the wafer surface may be reduced, thereby reducing the heating uniformity of the wafer.

Based on the above, the present disclosure provides a method of wafer bonding. The wafer surface is treated with water, thereby improving the heating uniformity of the wafer during bonding, so as to obtain a structure with good bonding strength. In addition, before treating the wafer surface with water, the wafer can be treated with plasma, which can reduce the temperature of the annealing process during bonding, thereby saving energy required for bonding, increasing productivity, and prevent high temperatures from affecting the performance of the overall structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A method of wafer bonding, comprising:
receiving a handle wafer and a device wafer;
coating a first surface of the handle wafer, a second surface of the device wafer, or a combination thereof with water, wherein
when the first surface of the handle wafer is coated with the water, the handle wafer rotates at a first rotational speed;
when the second surface of the device wafer is coated with the water, the device wafer rotates at a second rotational speed; and
when the first surface of the handle wafer and the second surface of the device wafer are coated with the water, the handle wafer rotates at a third rotational speed, and the device wafer rotates at a fourth rotational speed; and
bonding the first surface of the handle wafer and the second surface of the device wafer.

2. The method of claim 1, wherein the water has a resistance value ranging from about 0.5 MΩ·cm to about 18.3 MΩ·cm.

3. The method of claim 1, wherein the first rotational speed, the second rotational speed, the third rotational speed, and the fourth rotational speed are independently about 1500 rpm to about 3500 rpm.

4. The method of claim 1, further comprising: before coating the first surface of the handle wafer, the second surface of the device wafer, or the combination thereof with the water, treating the first surface, the second surface, or the combination thereof with plasma.

5. The method of claim 4, wherein during treating the first surface of the handle wafer, the second surface of the device wafer, or the combination thereof with the plasma, a bombardment time of the plasma is from 15 seconds to 30 seconds.

6. The method of claim 4, wherein the plasma comprises an oxygen plasma, a nitrogen plasma, an argon plasma, or combinations thereof.

7. The method of claim 1, wherein coating the first surface of the handle wafer, the second surface of the device wafer, or the combination thereof with the water comprises:
providing the water and a gas with a nozzle to spray the water onto the first surface, the second surface, or the combination thereof.

8. The method of claim 7, wherein when providing the water and the gas with the nozzle, a flow rate of the water is about 0.14 L/min to about 0.22 L/min, and a flow rate of the gas is about 40 L/min to about 75 L/min.

9. The method of claim 1, wherein at least one of the handle wafer and the device wafer comprises a wafer body and an insulating layer, and the insulating layer covers the wafer body.

10. The method of claim 1, wherein bonding the first surface of the handle wafer and the second surface of the device wafer is performed at about 180° C. to about 1100° C.

11. The method of claim 10, wherein bonding the first surface of the handle wafer and the second surface of the device wafer is performed at about 180° C. to about 600° C.

12. A method of wafer bonding, comprising:
receiving a handle wafer and a device wafer;
treating a first surface of the handle wafer, a second surface of the device wafer, or a combination thereof with plasma;
coating the first surface treated with the plasma, the second surface treated with the plasma, or a combination thereof with water; and
bonding the first surface of the handle wafer and the second surface of the device wafer.

13. The method of claim 12, wherein the plasma comprises an oxygen plasma, a nitrogen plasma, an argon plasma, or combinations thereof.

14. The method of claim 12, wherein bonding the first surface of the handle wafer and the second surface of the device wafer is performed at about 180° C. to about 1100° C.

15. The method of claim 12, wherein at least one of the handle wafer and the device wafer comprises a wafer body and an insulating layer, and the insulating layer covers the wafer body.

16. The method of claim 12, wherein the water has a resistance value ranging from about 0.5 MΩ·cm to about 18.3 MΩ·cm.

17. The method of claim 12, wherein the water does not comprise ammonia, a chelating agent, a surfactant, or combinations thereof.

18. The method of claim 12, wherein during treating the first surface of the handle wafer, the second surface of the device wafer, or the combination thereof with the plasma, a bombardment time of the plasma is from 15 seconds to 30 seconds.

19. The method of claim 12, wherein coating the first surface treated with the plasma, the second surface treated with the plasma, or the combination thereof with the water comprises:
providing the water and a gas with a nozzle to spray the water onto the first surface, the second surface, or the combination thereof.

20. The method of claim 12, further comprising: before treating the first surface of the handle wafer, the second surface of the device wafer, or the combination thereof with the plasma, generating the plasma by an upper electrode and a lower electrode, wherein the upper electrode and the lower electrode are respectively connected to radio frequency power supplies with a frequency of about 40 kHz to about 400 KHz.
